(19) United States
(12) Patent Application Publication
(10) Pub. No.: US 2023/0403883 A1
(43) Pub. Date: Dec. 14, 2023

(54) DISPLAY DEVICE AND METHOD FOR MANUFACTURING THE SAME

(71) Applicant: Samsung Display Co., Ltd., Yongin-si (KR)

(72) Inventors: JONGHYUN YUN, Suwon-si (KR); JUNYOUNG KIM, Suwon-si (KR); YURI OH, Suwon-si (KR); HYUNG JOO JUN, Asan-si (KR)

(21) Appl. No.: 18/127,801

(22) Filed: Mar. 29, 2023

(30) Foreign Application Priority Data
Jun. 9, 2022 (KR) 10-2022-0070154

(51) Int. Cl. H10K 59/122; H10K 71/20; H10K 59/12

(52) U.S. Cl. CPC H10K 59/122; H10K 71/233; H10K 59/1201

(57) ABSTRACT

A display device includes a plurality of pixel electrodes spaced apart from each other, in which each pixel electrode includes a central part and a peripheral part surrounding the central part, a pixel defining layer disposed on the plurality of pixel electrodes and including an overlap part overlapping the peripheral part when viewed in a plan view, and a lateral side to define a pixel opening exposing the central part, in which a portion of the overlap part has an undercut, a light emitting material disposed on the central part exposed through the pixel opening, and a common electrode including a first part disposed on the light emitting material on the central part and a second part disposed on the pixel defining layer, in which the first part is disconnected from the second part along the undercut portion.

### CROSS-REFERENCE TO RELATED APPLICATION

This application claims priority under 35 USC § 119 to Korean Patent Application No. 10-2022-0070154 filed on Jun. 9, 2022, in the Korean Intellectual Property Office (KIPO), the entire disclosure of which is incorporated herein by reference.

### BACKGROUND

### 1. Field

Embodiments of the present disclosure relate to an organic light emitting display device and a method for manufacturing the organic light emitting display device.

### 2. Description of the Related Art

In general, a display device, which displays an image, may include a plurality of pixels to emit light. Each of the plurality of pixels may include a pixel electrode, a common electrode, and a light emitting material interposed between the pixel electrode and the common electrode.

The plurality of pixels may share the common electrode. Accordingly, a current may leak between two pixels, which are disposed adjacent to each other, of the plurality of pixels, which degrades the display performance of the display device.

### SUMMARY

An object of the present disclosure provides a display device improved in display performance.

Another object of the present disclosure provides a method for manufacturing the display device.

However, objects of the present disclosure are not limited by the above-described object, and may be variously expanded without departing from the idea and scope of the present disclosure.

In order to achieve the above object of the present disclosure, according to one embodiment of the present disclosure, a display device includes a plurality of pixel electrodes spaced apart from each other, in which each pixel electrode includes a central part and a peripheral part surrounding the central part, a pixel defining layer disposed on the plurality of pixel electrodes, the pixel defining layer including an overlap part overlapping the peripheral part in a plan view and a lateral side which exposes the central part to define a pixel opening, in which a portion of the overlap part has an undercut portion which is recessed from the lateral side, a light emitting material disposed on the central part exposed through the pixel opening, and a common electrode including a first part disposed on the light emitting material on the central part and a second part disposed on the pixel defining layer, in which the common electrode has a disconnected portion along the undercut portion.

According to one embodiment, the pixel defining layer may have a forward-tapered shape with respect to the plurality of pixel electrodes, and the undercut portion may be recessed from the lateral side of the pixel defining layer in a direction from the central part toward the peripheral part.

According to one embodiment, a height of the undercut portion may be gradually decreased in the direction from the central part toward the peripheral part.

According to one embodiment, a height of the undercut portion which is disposed adjacent to the central part may be higher than a height of the light emitting material disposed on the central part.

According to one embodiment, the plurality of pixel electrodes may include a first pixel electrode and a second pixel electrode disposed adjacent to each other. The undercut portion may include a first undercut portion overlapping a peripheral part of the first pixel electrode, in the plan view, and a second undercut portion overlapping a peripheral part of the second pixel electrode, in the plan view. The first undercut portion and the second undercut portion may be interposed between a central part of the first pixel electrode and a central part of the second pixel electrode.

According to one embodiment, a portion of the second part which does not overlap the undercut portion when viewed in a plan view electrically come into contact with the first part.

According to one embodiment, each of the plurality of pixel electrodes may include an extension part that extends from an outer portion of the each of the plurality of pixel electrodes in a direction from the central part to the peripheral part and does not overlap the undercut portion of the peripheral part when viewed in a plan view.

According to one embodiment, the pixel defining layer may directly contact with the extension part.

According to one embodiment, the pixel defining layer may further include a groove overlapping the undercut portion in the plan view, and recessed in a direction from a top surface of the pixel defining layer toward a top surface of the peripheral part.

According to one embodiment, the pixel defining layer may include a positive photoresist material.

In order to achieve the above object of the present disclosure, according to another embodiment of the present disclosure, a method for manufacturing a display device includes forming a plurality of pixel electrodes spaced apart from each other, in which each pixel electrode includes a central part and a peripheral part surrounding the central part, forming a preliminary-pixel defining layer to cover the plurality of pixel electrodes, removing a portion of the preliminary-pixel defining layer to form a pixel defining layer including an overlap part overlapping the peripheral part in a plan view, and a lateral side defining a pixel opening exposing the central part, in which a portion of the overlap part has an undercut portion which is recessed from the lateral side, forming a light emitting material on the central part exposed through the pixel opening, and forming a common electrode including a first part disposed on the light emitting material on the central part and a second part disposed on the pixel defining layer, in which the common electrode has a disconnected portion along the undercut portion.

According to one embodiment, the removing of the portion of the preliminary-pixel defining layer may include aligning a mask having an exposure opening on the preliminary-pixel defining layer, exposing the preliminary-pixel defining layer, and developing an exposed portion of the preliminary-pixel defining layer using a developer.

According to one embodiment, the developer may be infiltrated into an interface between the peripheral part and the preliminary-pixel defining layer to form the undercut portion.

According to one embodiment, the method for manufacturing the display device may further include forming a through pattern in the preliminary-pixel defining layer which exposes a top surface of the peripheral part through the preliminary-pixel defining layer after forming the preliminary-pixel defining layer.

According to one embodiment, the developer may be infiltrated into an interface between the peripheral part and the preliminary-pixel defining layer through the through pattern to form the undercut portion.

According to one embodiment, the method for manufacturing the display device may further include curing the preliminary-pixel defining layer after developing the exposed portion of the preliminary-pixel defining layer using the developer.

According to one embodiment, the pixel defining layer may have a forward-tapered shape with respect to the plurality of pixel electrodes, and the undercut portion may be recessed from the lateral side of the pixel defining layer in a direction from the central part toward the peripheral part.

According to one embodiment, a height of the undercut portion may be gradually decreased in the direction from the central part toward the peripheral part.

According to one embodiment, a height of the undercut portion, which is disposed adjacent to the central part, may be higher than a height of the light emitting material disposed on the central part.

According to one embodiment, the plurality of pixel electrodes may include a first pixel electrode and a second pixel electrode disposed adjacent to each other, the undercut portion may include a first undercut portion overlapping a peripheral part of the first pixel electrode, in the plan view, a second undercut portion overlapping a peripheral part of the second pixel electrode in the plan view, and the first undercut portion and the second undercut portion may be interposed between a central part of the first pixel electrode and a central part of the second pixel electrode.

The display device according to embodiments may include a plurality of pixel electrodes spaced apart from each other, in which each pixel electrode includes a central part and a peripheral part surrounding the central part, a pixel defining layer disposed on the plurality of pixel electrodes, including an overlap part overlapping the peripheral part, when viewed in a plan view, and a lateral side to define a pixel opening, which exposes the central part, in which a portion of the overlap part has an undercut portion, a light emitting material disposed on the central part exposed through the pixel opening, and a common electrode including a first part disposed on the light emitting material and a second part disposed on the pixel defining layer, in which the first part is disconnected from the second part in a region adjacent to the undercut portion. As the first part is disconnected from the second part, the current may be prevented from leaking between the two pixels disposed adjacent to each other, and the display performance of the display device may be improved.

A method for manufacturing a display device according to embodiments may include forming a preliminary-pixel defining layer to cover the plurality of pixel electrodes, removing a portion of the preliminary-pixel defining layer to form a pixel defining layer including an overlap part overlapping the peripheral part, when viewed in a plan view, and a lateral side to define a pixel opening, which exposes the central part, in which a portion of the overlap part is spaced apart from the peripheral part to define an exited space, forming a light emitting material on the central part exposed through the pixel opening, and forming a common electrode including a first part disposed on the light emitting material and a second part disposed on the pixel defining layer, in which the first part is spaced apart from a portion, which overlaps an undercut portion when viewed in a plan view, of the second part. Accordingly, the display device may be provided with improved display performance.

However, effects of the present disclosure are not limited to the above-described effects, and may be variously expanded without departing from the idea and scope of the present disclosure.

### BRIEF DESCRIPTION OF THE DRAWINGS

FIG. 1 is a plan view for describing a display device according to embodiments of the present disclosure;

FIGS. 2, 3 and 4 are views for describing a pixel according to an embodiment of the present disclosure;

FIGS. 5, 6, 7, 8, 9, 10 and 11 are views for describing a method for manufacturing a pixel according to an embodiment of the present disclosure;

FIGS. 12, 13 and 14 are views for describing a pixel according to another embodiment of the present disclosure; and

FIGS. 15, 16, 17, 18, 19, 20, 21 and 22 are views for describing a method for manufacturing a pixel according to another embodiment of the present disclosure.

### DETAILED DESCRIPTION OF THE EMBODIMENTS

Hereinafter, a display device according to embodiments of the present disclosure and a method for manufacturing the display device will be described with reference to accompanying drawings. The same or similar reference numerals will be used for the same components in the accompanying

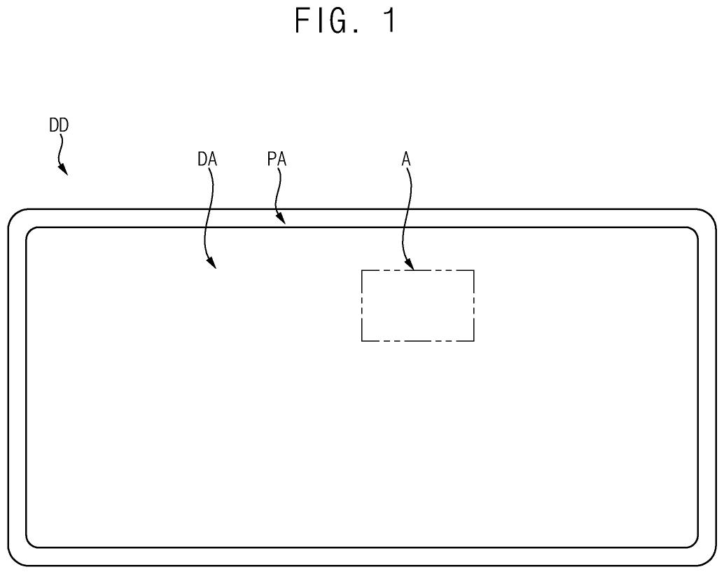

FIG. 1 is a plan view for describing a display device according to embodiments of the present disclosure.

Referring to FIG. 1, a display device DD may include a display region DA and a peripheral region PA.

The display region DA may be a region for displaying an image. The display device DD may include a plurality of pixels disposed in the display region DA. Each of the plurality of pixels may receive an electrical signal to emit light having brightness corresponding to the strength of the electrical signal.

The peripheral region PA may be disposed adjacent to at least one side of the display region DA. For example, as illustrated in FIG. 1, the peripheral region PA may surround the display region DA. The peripheral region PA may be a region in which the image is not displayed. The display device DD may include driving units disposed in the peripheral region PA and the driving unit may generate the electrical signal.

According to an embodiment, the peripheral region PA may be omitted. In this case, an image may be displayed on a front surface of the display device DD.

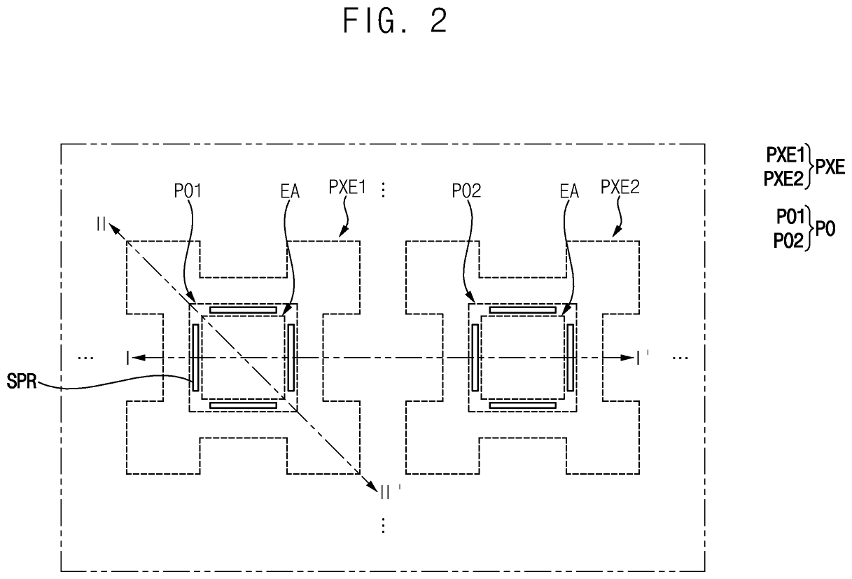

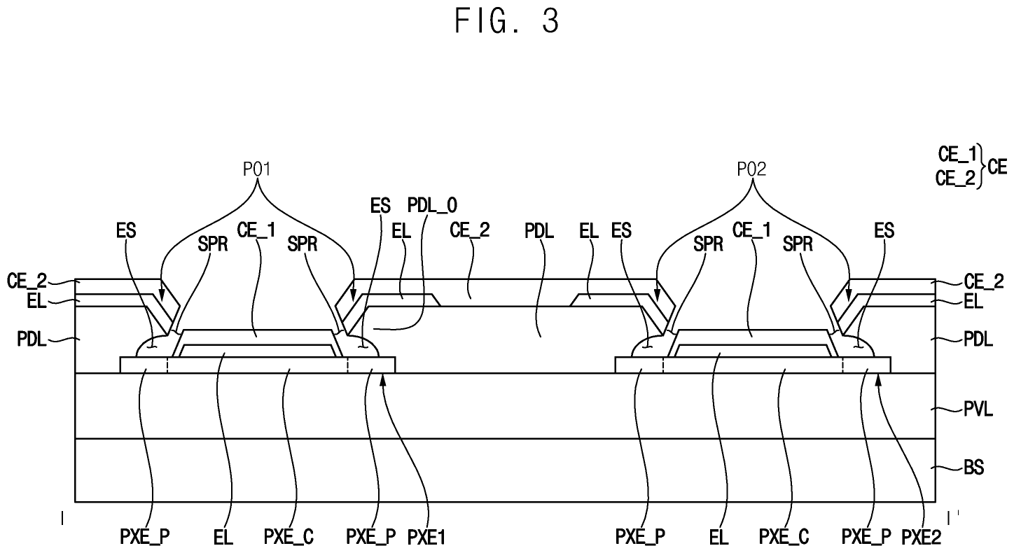

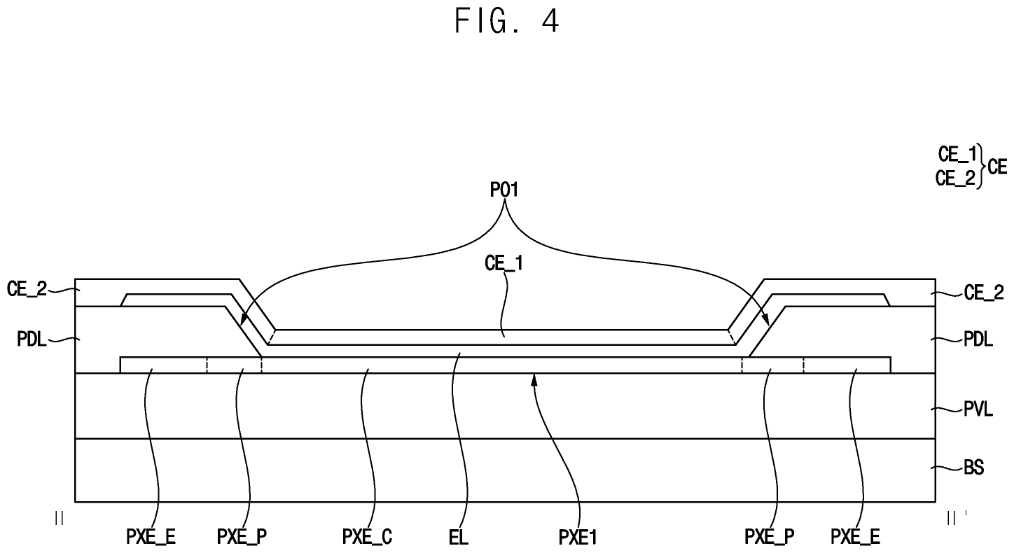

FIGS. 2 to 4 are views for describing a pixel according to an embodiment of the present disclosure. FIG. 2 is a plan view illustrating a plurality of pixels disposed in region A of FIG. 1, FIG. 3 is a cross-sectional view taken along line I-I′ of FIG. 2, and FIG. 4 is a cross-sectional view taken along II-II′ of FIG. 4.

Referring to FIGS. 2 to 4, each of the plurality of pixels may include a base substrate BS, a passivation layer PVL, a pixel electrode PXE, a light emitting material EL, a pixel defining layer PDL, and a common electrode CE.

The base substrate BS may include glass or plastic. At least two transistors are disposed on the base substrate BS. According to an embodiment, the base substrate BS may include a material having flexibility to be repeatedly folded or unfolded.

The passivation layer PVL may be disposed on the base substrate BS. The passivation layer PVL may include an inorganic insulating material or an organic insulating material. A top surface of the passivation layer PVL may be substantially flat.

The pixel electrode PXE may be disposed on the passivation layer PVL. The pixel electrode PXE may include a conductive material. According to an embodiment, the pixel electrode PXE may be referred to as an anode electrode. The pixel electrode PXE may include a first pixel electrode PXE1 and a second pixel electrode PXE2 spaced apart from the first pixel electrode PXE1. According to an embodiment, the first pixel electrode PXE1 may be referred to as a first anode electrode of a first pixel, and the second pixel electrode PXE2 may be referred to as a second anode electrode of a second pixel which is disposed adjacent to the first pixel.

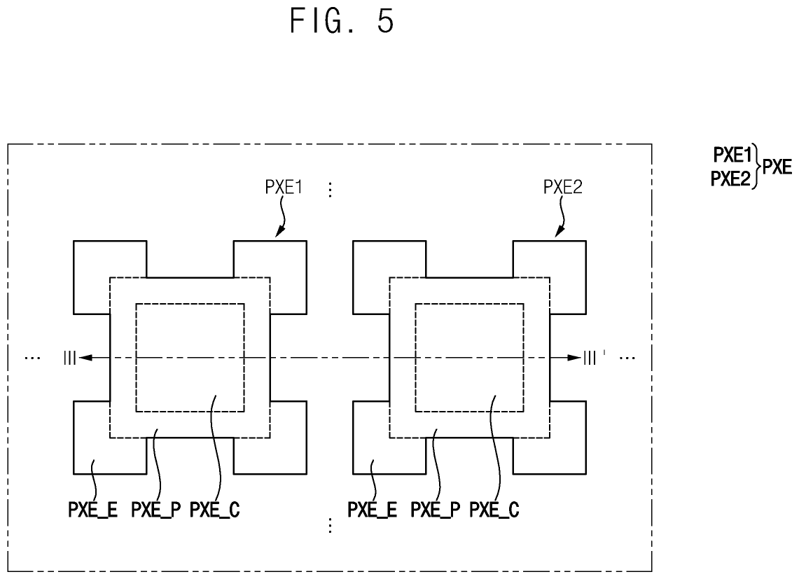

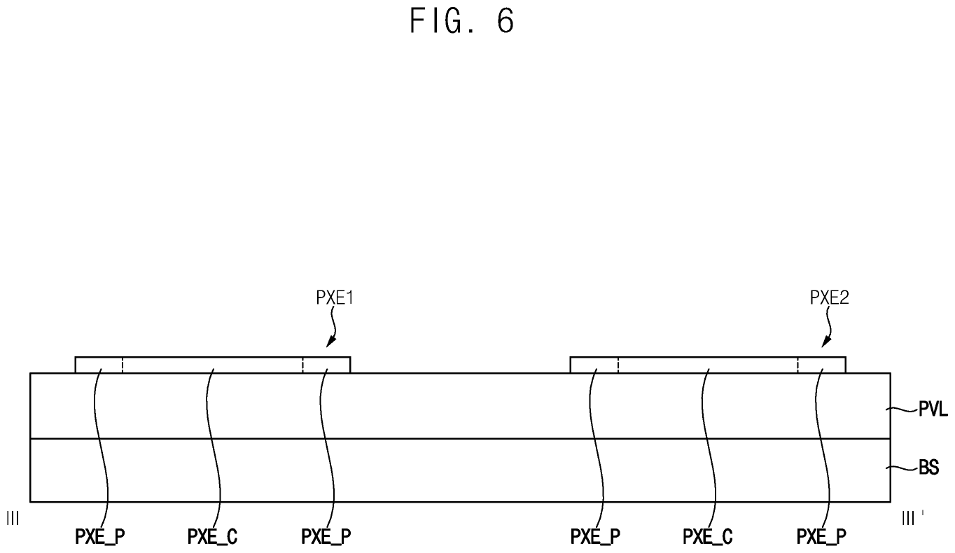

The pixel electrode PXE may include a central part PXE_C, a peripheral part PXE_P, and an extension part PXE_E. The peripheral part PXE_P may surround the central part PXE_C. The extension part PXE_E may be a part that extends from the peripheral part PXE_P toward an outside of the peripheral part PXE_P. The central part PXE_C, the peripheral part PXE_P, and the extension part PXE_E will be described in detail with reference to FIGS. 5 and 6.

The pixel electrode PXE may be disposed on the passivation layer PVL. A portion of the pixel defining layer PDL may be disposed on the peripheral part PXE_P and the extension part PXE_E. In other words, the portion of the pixel defining layer PDL may overlap the peripheral part PXE_P and the extension part PXE_E when viewed in a plan view. The portion of the pixel defining layer PDL which overlaps the peripheral part PXE_P when viewed in a plan view may be referred to as an overlap part PDL_0.

The pixel defining layer PDL may include an organic insulating material. According to an embodiment, the organic insulating material may be a positive photoresist material.

A lateral side of the pixel defining layer PDL may define a pixel opening to expose the central part PXE_C. For example, the lateral side of the pixel defining layer PDL may define a first pixel opening PO1 to expose the central part PXE_C of the first pixel electrode PXE1 and a second pixel opening PO2 to expose the central part PXE_C of the second pixel electrode PXE2. According to an embodiment, the pixel defining layer PDL may have a forward-tapered shape with respect to the pixel electrode PXE.

A portion of the overlap part PDL_0 may have an undercut portion ES. As illustrated in FIG. 3, the undercut portion ES may be a recessed portion of the pixel defining layer PDL which is recessed from the lateral side of the pixel defining layer PDL in a direction from the central part PXE_C to the peripheral part PXE_P. In addition, the height of the undercut portion ES may be gradually decreased from the central part PXE_C toward the peripheral part PXE_P.

The pixel defining layer PDL may directly contact with the extension part PXE_E. In other words, the pixel defining layer PDL may not be spaced apart from the extension part PXE_E. Accordingly, an empty space may not be defined between the pixel defining layer PDL and the extension part PXE_E.

The light emitting material EL may be disposed on the central part PXE_C exposed by the pixel opening. In addition, the light emitting material EL may be disposed on the pixel defining layer PDL. In this case, a portion of the light emitting material EL which is disposed on the pixel defining layer PDL may have a disconnected portion along the undercut portion ES of the pixel defining layer PDL. The light emitting material EL may receive an electrical signal to emit light having brightness corresponding to the strength of the electrical signal. For example, the light emitting material EL disposed on the central part PXE_C may emit light. In this case, the light emitting material EL disposed on the central part PXE_C may define a light emitting region EA. According to an embodiment, the light emitting material EL may include an organic light emitting material.

The common electrode CE may be disposed on the light emitting material EL and the pixel defining layer PDL. Specifically, the common electrode CE may include a first part CE_1 disposed on the light emitting material EL on the central part PXE_C and a second part CE_2 disposed on the pixel defining layer PDL. The common electrode CE may include a conductive material. According to an embodiment, the common electrode PXE may be referred to as a cathode electrode.

As illustrated in FIGS. 2 and 3, according to the present disclosure, the common electrode 1 may have a disconnected portion along the undercut portion ES of the pixel defining layer PDL and the disconnected portion may define a short-circuit space SPR. The short-circuit space SPR may be formed by the undercut portion ES. In other words, a portion of the common electrode CE is disconnected along the undercut portion ES due to a poor step coverage of a material forming the common electrode CE, such that the short-circuit space SPR is formed.

As illustrated in FIGS. 2 and 4, according to the present disclosure, a portion, which does not overlap the undercut portion ES when viewed in a plan view, of the second part CE_2 may electrically come into contact with the first part CE_1. Since the portion, which does not overlap the undercut portion ES when viewed in a plan view, of the second part CE_2 electrically come into contact with the first part CE_1, the substantially same electrical signal may be applied to the first part CE_1 and the second part CE_2.

According to an embodiment, the undercut portion ES may be positioned between the central parts PXE_C of two adjacent pixels of the plurality of pixels. For example, as illustrated in FIGS. 2 and 4, the undercut portion ES overlapping the peripheral part PXE_P of the first pixel electrode PXE1 and the undercut portion ES overlapping the peripheral part PXE_P of the second pixel electrode PXE2 may be interposed between the central part PXE_C of the first pixel electrode PXE1 and the central part PXE_C of the second pixel electrode PXE2. Accordingly, the short-circuit space SPR may be interposed between the light emitting material EL disposed on the center PXE_C of the first pixel electrode PXE1 and the light emitting material EL disposed on the center PXE_C of the second pixel electrode PXE2, and a current may not leak between two adjacent pixels.

When the height of the light emitting material EL disposed on the central part PXE_C is higher than or substantially equal to the height of the undercut portion ES in a region adjacent to the central part PXE_C, the first part CE_1 may electrically come into contact with the second part CE_2 overlapping the undercut portion ES, when viewed in a plan view. In this case, current leakage may occur between two adjacent pixels. Accordingly, as illustrated in FIG. 3, the height of the undercut portion ES in the region adjacent to the central part PXE_C may be higher than the height of the light emitting material EL.

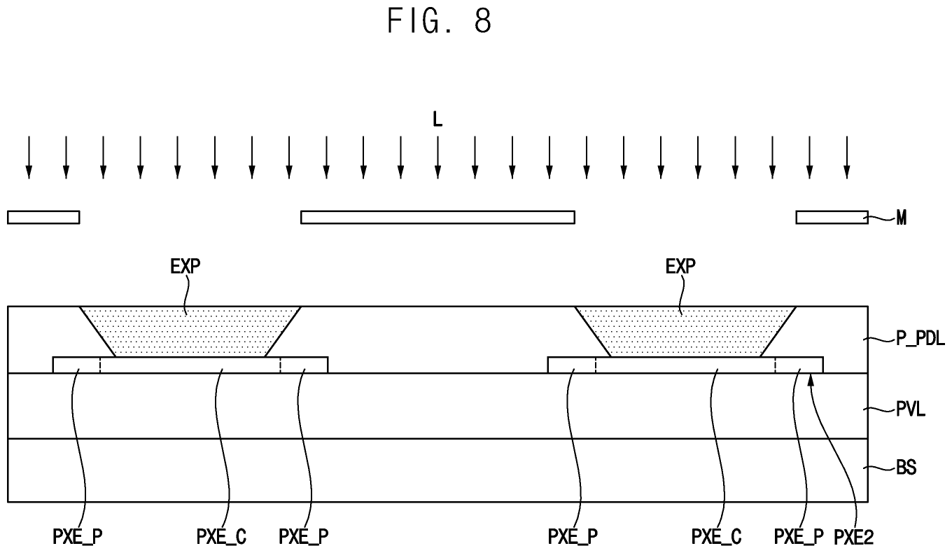

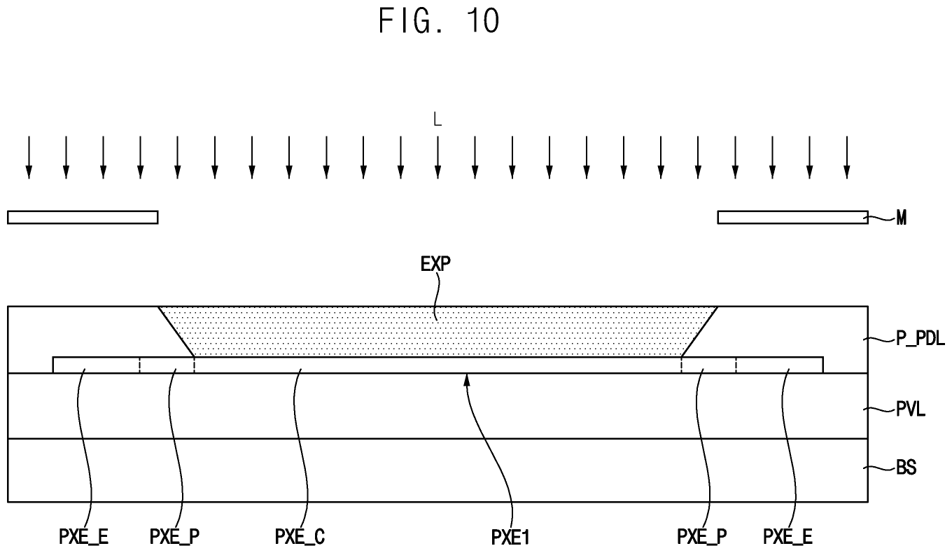

FIGS. 5 to 11 are views for describing a method for manufacturing a pixel according to an embodiment of the present disclosure. FIGS. 5 to 11 illustrate a method for manufacturing a pixel, which is described with reference to FIGS. 2 to 4. Accordingly, the duplication of the description of components of FIGS. 5 TO 11, which are substantially the same as components described with reference to FIGS. 2 to 4 will be omitted to avoid redundancy.

Referring to FIGS. 5 and 6, the passivation layer PVL may be formed on the base substrate BS, and the pixel electrode PXE may be formed on the passivation layer PVL. The pixel electrode PXE may be formed by depositing a conductive material on the passivation layer PVL and then patterning the conductive material.

The pixel electrode PXE may include a plurality of pixel electrodes spaced apart from each other. The plurality of pixel electrodes may include the first pixel electrode PXE1 and the second pixel electrode PXE2.

The pixel electrode PXE may include the central part PXE_C, the peripheral part PXE_P, and the extension part PXE_E. The peripheral part PXE_P may surround the central part PXE_C, when viewed in a plan view. The extension part PXE_E may be a part extending in a direction from the central part PXE_C to the peripheral part PXE_P, from the outside of the peripheral part PXE_P, when viewed in a plan view.

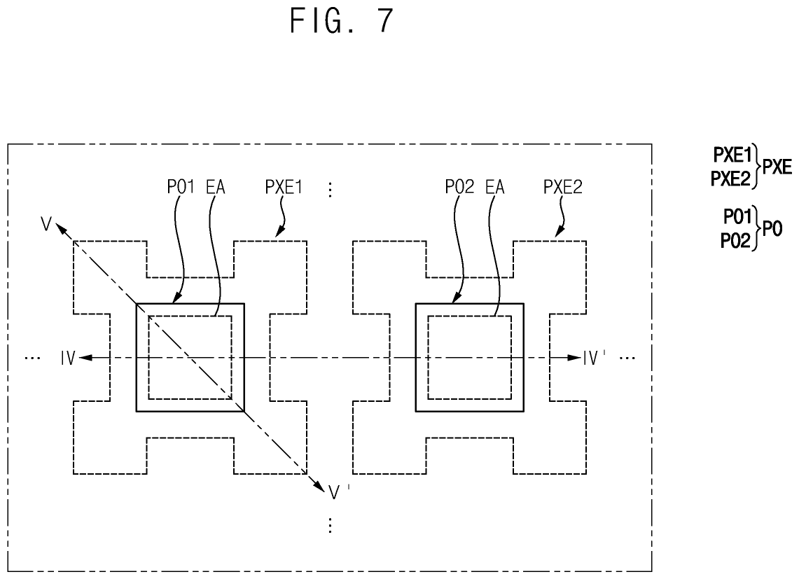

Referring to FIGS. 7 to 11, a preliminary-pixel defining layer P_PDL may be formed on the pixel electrode PXE and the passivation layer PVL. The preliminary-pixel defining layer P_PDL may include an organic insulating material. According to an embodiment, the organic insulating material may be a positive photoresist material.

The pixel defining layer PDL may be formed by removing a portion of the preliminary-pixel defining layer P_PDL. In the step of removing the portion of the preliminary-pixel defining layer P_PDL, a mask M having an exposure opening may be disposed on the preliminary-pixel defining layer P_PDL, the preliminary-pixel defining layer P_PDL may be exposed (see reference numeral “L”), and an exposure part EXP of the preliminary-pixel defining layer EXP may be developed using a developer. In this case, the exposure opening may be disposed to correspond to the central part PXE_C. Accordingly, the pixel defining layer PDL may be formed while including the lateral side defining a pixel opening (e.g., the first pixel opening PO1 and the second pixel opening PO2) exposing the central part PXE_C. In this case, the pixel defining layer PDL may have a forward tapered shape with respect to the pixel electrode PXE.

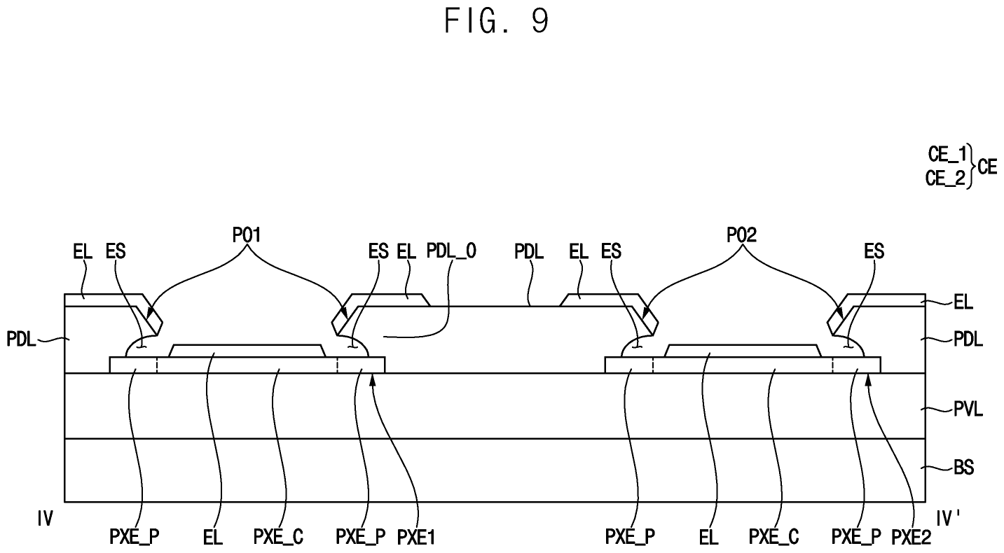

The developer may be infiltrated into an interface between the peripheral part PXE_P and the preliminary-pixel defining layer P_PDL. Accordingly, as illustrated in FIG. 9, a portion of the pixel defining layer PDL which overlaps the peripheral part PXE_P when viewed in a plan view may have an undercut portion ES. The portion, which overlaps the peripheral part PXE_P of the pixel defining layer PDL when viewed in a plan view may be referred to as the overlap part PDL_0. The undercut portion ES may have a shape recessed from the lateral side of the pixel defining layer PDL in the direction from the central part PXE_C toward the peripheral part PXE_P. In addition, the height of the undercut portion ES may be gradually decreased from the central part PXE_C toward the peripheral part PXE_P.

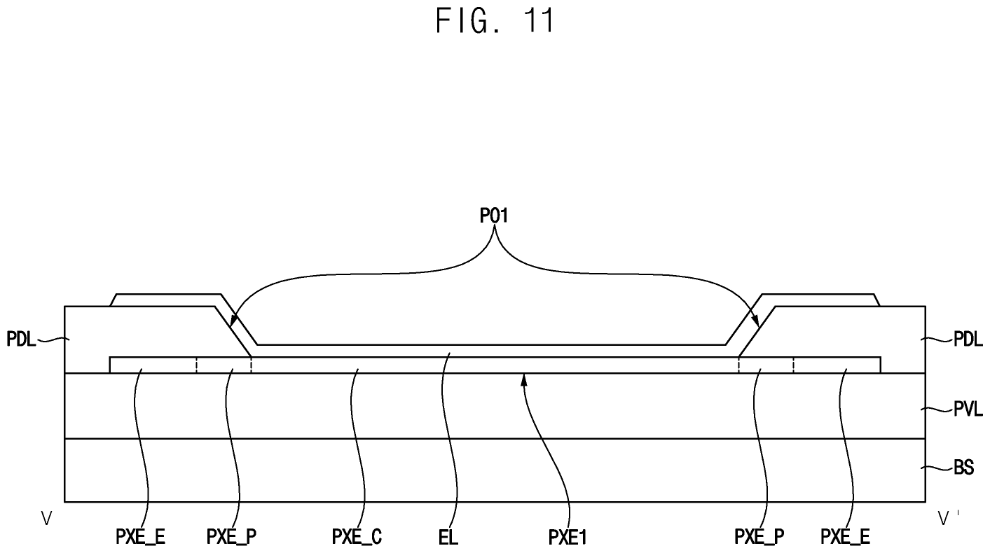

An area, in which the preliminary-pixel defining layer P_PDL makes contact with the pixel electrode PXE, may be relatively increased by the extension part PXE_E. Accordingly, the adhesion force between the preliminary-pixel defining layer P_PDL and the pixel electrode PXE may be relatively increased. Accordingly, as illustrated in FIG. 11, the peripheral part PXE_P adjacent to the extension part PXE_E may not have an undercut portion ES. In other words, the extension part PXE_E and the peripheral part PXE_P adjacent to the extension part PXE_E may directly contact with the pixel defining layer PDL.

The light emitting material EL may be formed on the central part PXE_C exposed by the pixel opening. In addition, the light emitting material EL may be disposed on the pixel defining layer PDL. In this case, the light emitting material EL may have a disconnected portion along the undercut portion ES of the pixel defining layer PDL. According to an embodiment, the height of the light emitting material EL disposed on the central part PXE_C may be less than the height of the undercut portion ES formed in the pixel defining layer PDL in a region adjacent to the central part PXE_C.

Referring to FIGS. 2 to 11, the common electrode CE may be formed on the light emitting material EL and the pixel defining layer PDL. The common electrode CE may include a first part CE_1 disposed on the light emitting material EL on the central part PXE_C and a second part CE_2 disposed on the pixel defining layer PDL. In this case, a portion of the common electrode CE which is disposed along the undercut portion ES when viewed in a plan view may have a disconnected portion due to the undercut portion ES.

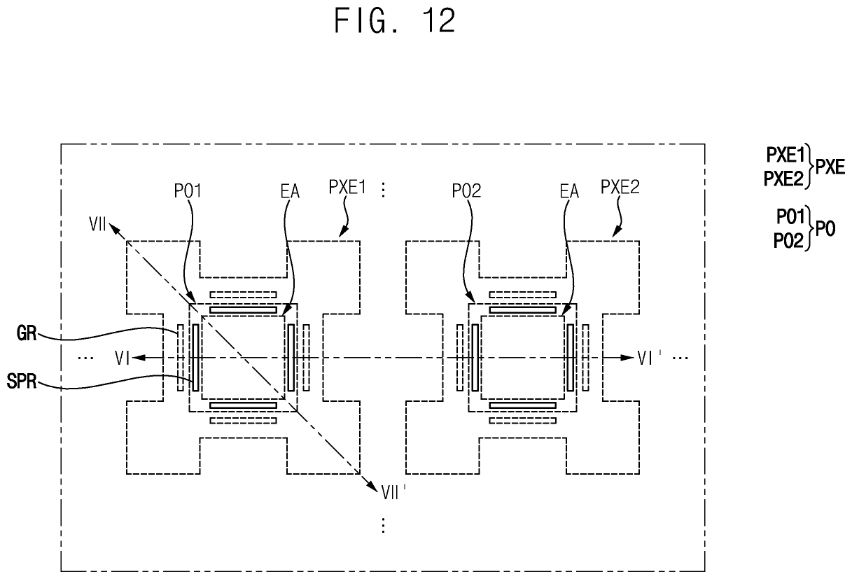

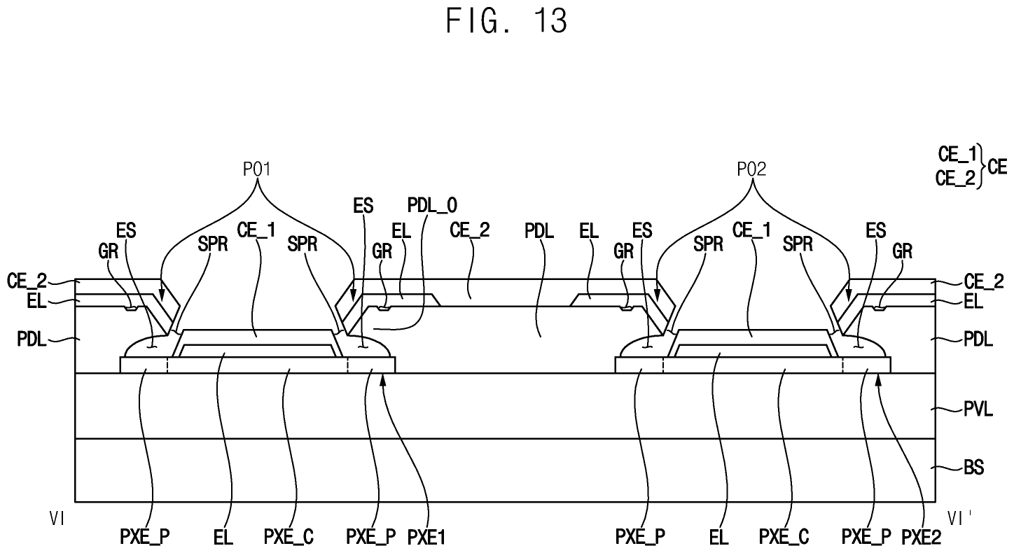

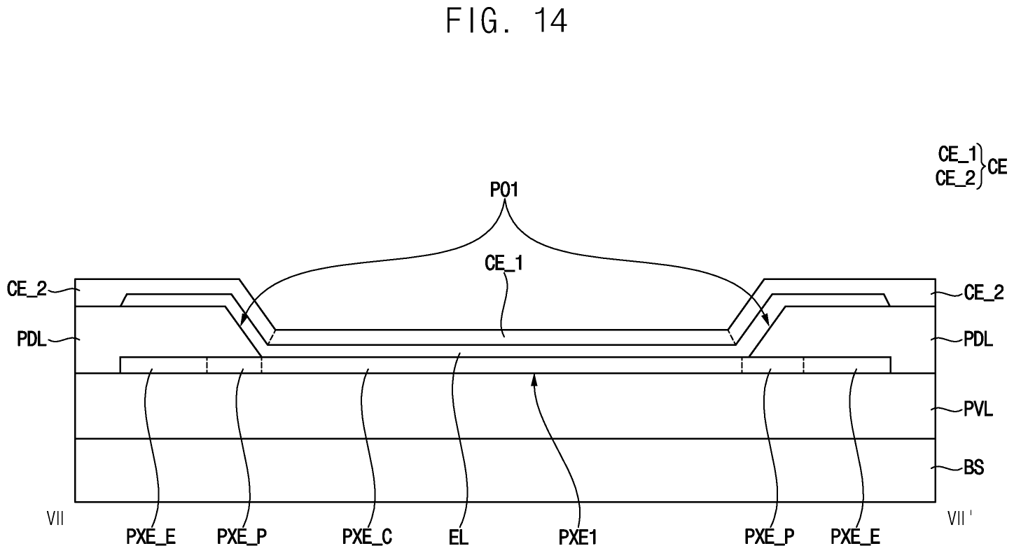

FIGS. 12 to 14 are views for describing a pixel according to another embodiment of the present disclosure. FIG. 12 is a plan view illustrating a plurality of pixels disposed in region A of FIG. 1, FIG. 13 is a cross-sectional view taken along line VI-VI′ of FIG. 12, and FIG. 14 is a cross-sectional view taken along VII-VII′ of FIG. 12.

As illustrated in FIGS. 12 to 14, according to another embodiment of the present disclosure, the pixel may be substantially the same as a pixel according to an embodiment of the present disclosure described with reference to FIGS. 2 to 4. Accordingly, the duplication of the description of components of FIGS. 12 to 14 the same as components described with reference to FIGS. 2 to 4 will be omitted to avoid redundancy.

Referring to FIGS. 12 to 14, the pixel defining layer PDL may include a groove GR. The groove GR may overlap the undercut portion ES. As illustrated in FIG. 13, the groove GR may be recessed in a direction from a top surface of the pixel defining layer PDL toward a top surface of the peripheral part PXE_P of the pixel electrode PXE. The groove GR may not pass through the pixel defining layer PDL.

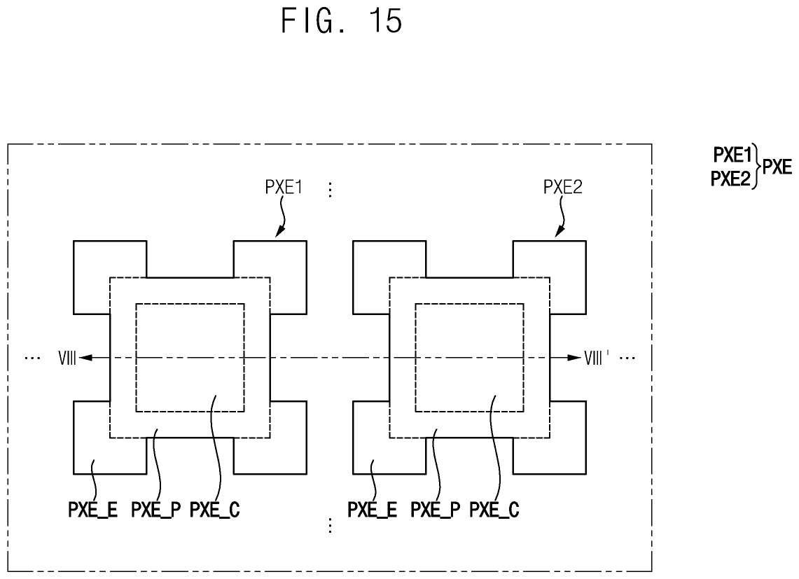

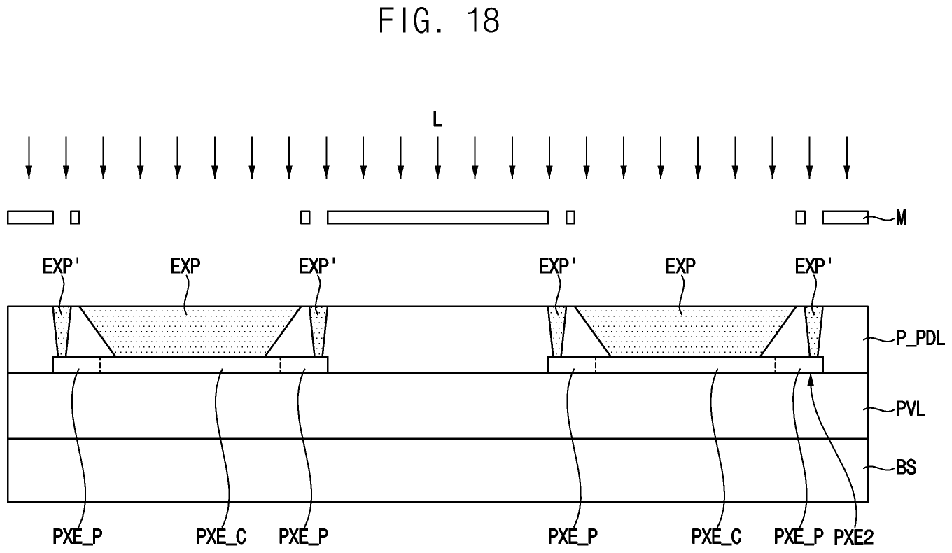

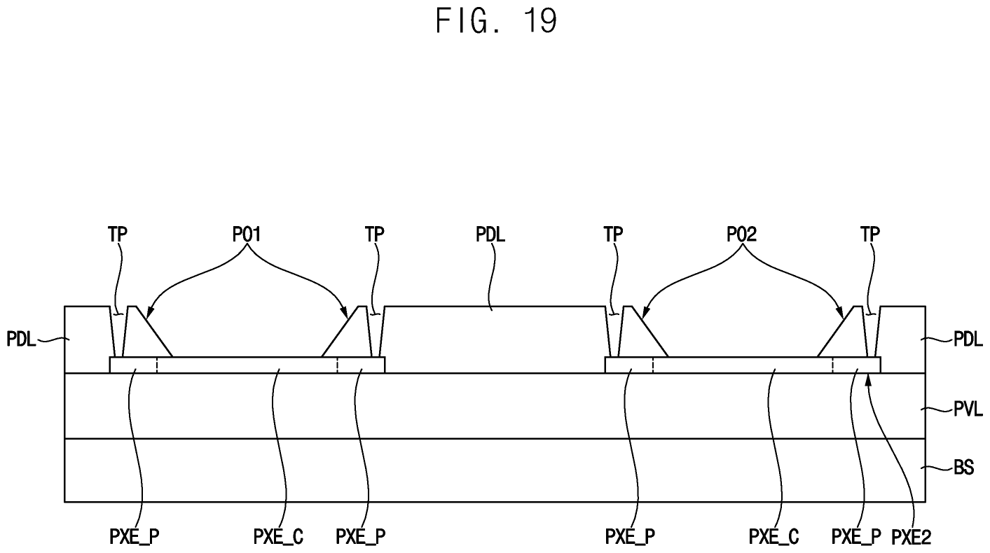

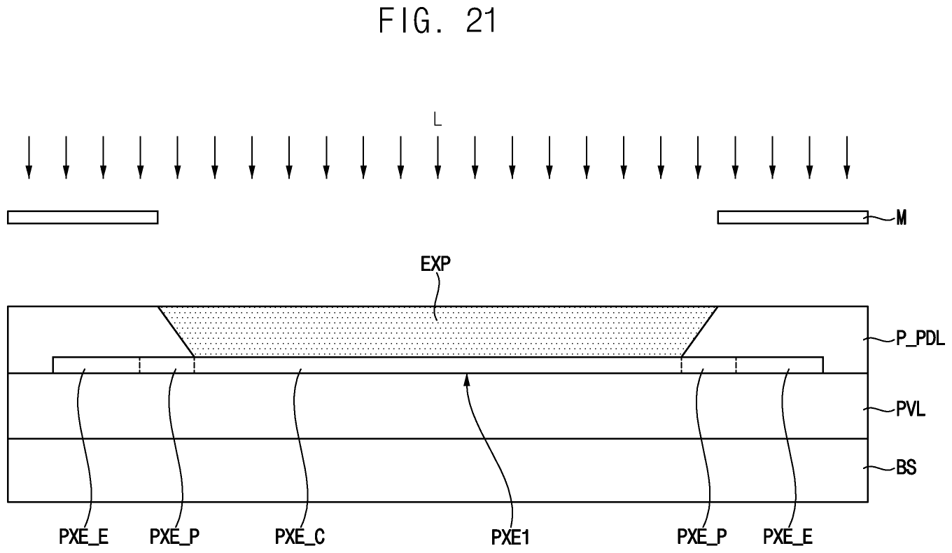

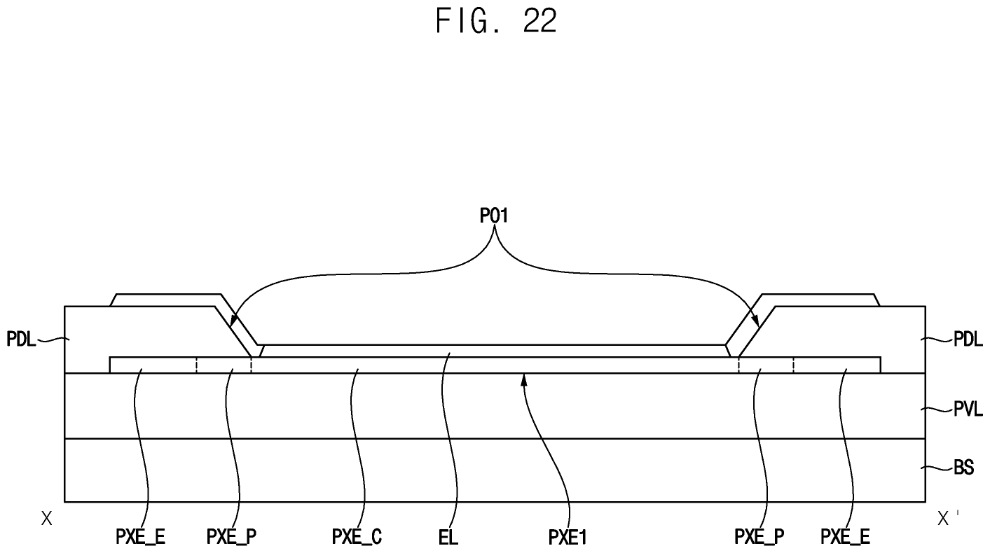

FIGS. 15 to 22 are views for describing a method for manufacturing a pixel according to another embodiment of the present disclosure. FIGS. 15 to 22 illustrate a method for manufacturing a pixel which is described with reference to FIGS. 12 to 14. Accordingly, the duplication of the description of components substantially the same as components described with reference to FIGS. 2 to 4, and FIGS. 12 to 14 will be omitted to avoid redundancy.

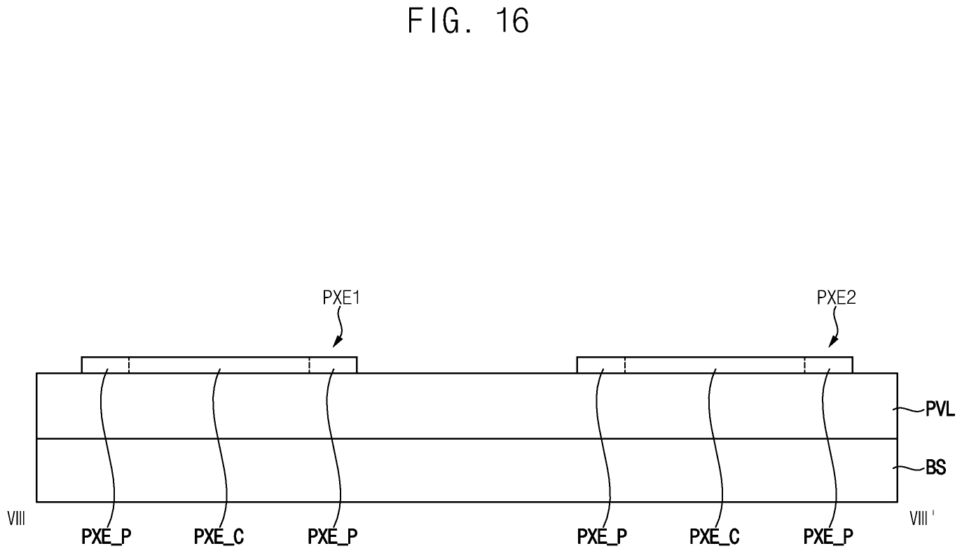

Referring to FIGS. 15 and 16, the passivation layer PVL may be formed on the base substrate BS, and the pixel electrode PXE may be formed on the passivation layer PVL. The pixel electrode PXE may be formed by depositing a conductive material on the passivation layer PVL and then patterning the conductive material.

The pixel electrode PXE may include a plurality of pixel electrodes spaced apart from each other. The plurality of pixel electrodes may include a first pixel electrode PXE1 and a second pixel electrode PXE2. The pixel electrode PXE may include a central part PXE_C, a peripheral part PXE_P, and an extension part PXE_E.

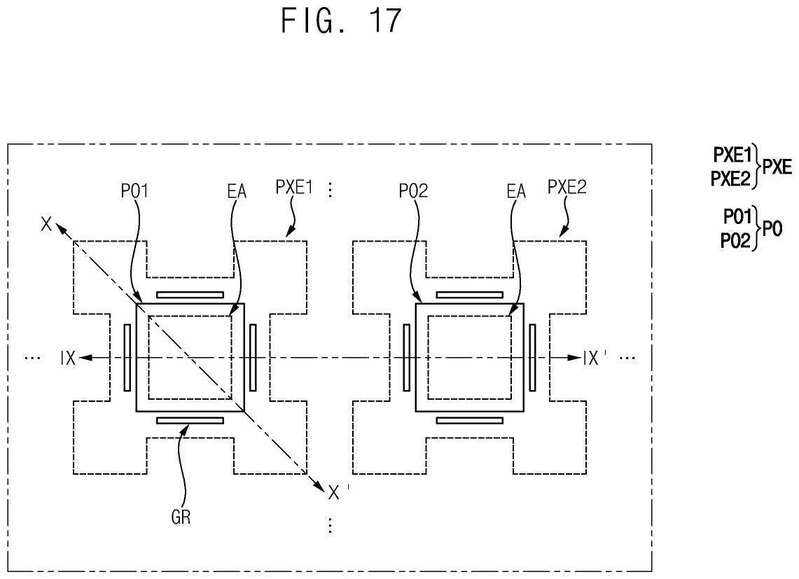

Referring to FIGS. 17 to 22, the pixel defining layer PDL may be formed by forming the preliminary-pixel defining layer P_PDL on the pixel electrode PXE and the passivation layer PVL, and then removing a portion of the preliminary-pixel defining layer P_PDL.

In the step of removing the portion of the preliminary-pixel defining layer P_PDL, a mask M having an exposure opening may be disposed on the preliminary-pixel defining layer P_PDL, the preliminary-pixel defining layer P_PDL may be exposed (see reference numeral “L”), and a first exposure part EXP and a second exposure part EXP′ of the preliminary-pixel defining layer EXP may be developed using a developer.

Accordingly, as the first exposure part EXP is developed, the pixel defining layer PDL may be formed while including the lateral side defining the pixel opening (e.g., the first pixel opening PO1 and the second pixel opening PO2) exposing the central part PXE_C. According to an embodiment, the pixel defining layer PDL may have a forward tapered shape with respect to the pixel electrode PXE.

As the second exposure part EXP′ is developed, a through pattern TP may be formed to expose a top surface of the peripheral part PXE_P.

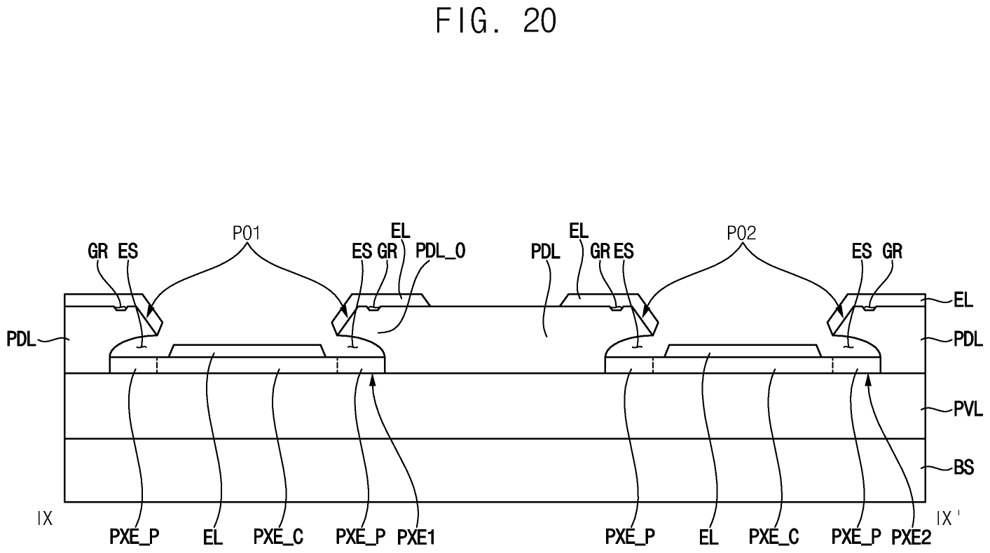

The developer may be infiltrated into the interface between the peripheral part PXE_P and the preliminary-pixel defining layer P_PDL. Accordingly, as illustrated in FIG. 20, the portion of the pixel defining layer PDL which overlaps the peripheral part PXE_P when viewed in a plan view may have the undercut portion ES.

When a through pattern TP is formed, the developer may be infiltrated into the interface between the peripheral part PXE_P and the preliminary-pixel defining layer P_PDL through the through pattern TP. Accordingly, the undercut portion ES may be effectively formed.

After the undercut portion ES is formed, a curing process may be performed. during the curing process, the through pattern TP is filled, and the groove GR may be formed in the top surface of the pixel defining layer PDL, such that the groove GR overlaps the undercut portion ES when viewed in a plan view.

The light emitting material EL may be formed on the central part PXE_C exposed by the pixel opening. In addition, the light emitting material EL may be disposed on the pixel defining layer PDL. In this case, a portion of the light emitting material EL may have a disconnected portion along the undercut portion ES.

Referring to FIGS. 12 to 22, the common electrode CE may be formed on the light emitting material EL and the pixel defining layer PDL. The common electrode CE may include a first part CE_1 disposed on the light emitting material EL on the central part PXE_C and a second part CE_2 disposed on the pixel defining layer PDL. In this case, a portion of the common electrode CE may have a disconnected portion along the undercut portion ES due to the step difference formed by the undercut portion ES.

Although an embodiment of the present disclosure has been described for illustrative purposes, those skilled in the art will appreciate that various modifications, and substitutions are possible, without departing from the scope and spirit of the present disclosure as disclosed in the accompanying claims.

The present disclosure is applicable to a display device and an electronic device including the same. For example, the present disclosure is applicable to a higher-resolution smart phone, a cellular phone, a smart pad, a smart watch, a tablet PC, a vehicle navigation system, a television, a computer monitor, or a laptop computer.

What is claimed is:

1. A display device comprising:
a plurality of pixel electrodes spaced apart from each other, wherein each pixel electrode includes a central part and a peripheral part surrounding the central part;
a pixel defining layer disposed on the plurality of pixel electrodes, the pixel defining layer including an overlap part overlapping the peripheral part when viewed in a plan view and a lateral side which exposes the central part to define a pixel opening, wherein a portion of the overlap part has an undercut portion which is recessed from the lateral side;
a light emitting material disposed on the central part exposed through the pixel opening; and
a common electrode including a first part disposed on the light emitting material on the central part and a second part disposed on the pixel defining layer, wherein the common electrode has a disconnected portion along the undercut portion.

2. The display device of claim 1, wherein the pixel defining layer has a forward-tapered shape with respect to the plurality of pixel electrodes, and
wherein the undercut portion is recessed from the lateral side of the pixel defining layer in a direction from the central part toward the peripheral part.

3. The display device of claim 2, wherein a height of the undercut portion is gradually decreased in the direction from the central part toward the peripheral part.

4. The display device of claim 1, wherein a height of the undercut portion which is disposed adjacent to the central part is higher than a height of the light emitting material disposed on the central part.

5. The display device of claim 1, wherein the plurality of pixel electrodes include a first pixel electrode and a second pixel electrode disposed adjacent to each other,
wherein the undercut portion includes:
a first undercut portion overlapping a peripheral part of the first pixel electrode when viewed in a plan view; and
a second undercut portion overlapping a peripheral part of the second pixel electrode when viewed in a plan view, and
wherein each of the first undercut portion and the second undercut portion is interposed between a central part of the first pixel electrode and a central part of the second pixel electrode.

6. The display device of claim 1, wherein a portion of the second part which does not overlap the undercut portion when viewed in a plan view electrically makes contact with the first part.

7. The display device of claim 1, wherein each of the plurality of pixel electrodes includes:
an extension part that extends from an outer portion of the each of the plurality of pixel electrodes in a direction from the central part to the peripheral part and does not overlap the undercut portion of the peripheral part when viewed in a plan view.

8. The display device of claim 7, wherein the pixel defining layer directly contacts with the extension part.

9. The display device of claim 1, wherein the pixel defining layer further includes:
a groove overlapping the undercut portion when viewed in a plan view and recessed in a direction from a top surface of the pixel defining layer toward a top surface of the peripheral part.

10. The display device of claim 1, wherein the pixel defining layer includes a positive photoresist material.

11. A method for manufacturing a display device, the method comprising:
forming a plurality of pixel electrodes spaced apart from each other, wherein each pixel electrode includes a central part and a peripheral part surrounding the central part;
forming a preliminary-pixel defining layer to cover the plurality of pixel electrodes;
removing a portion of the preliminary-pixel defining layer to form a pixel defining layer including an overlap part overlapping the peripheral part when viewed in a plan view, and a lateral side defining a pixel opening exposing the central part, wherein a portion of the overlap part has an undercut portion which is recessed from the lateral side;
forming a light emitting material on the central part exposed through the pixel opening; and
forming a common electrode including a first part disposed on the light emitting material on the central part and a second part disposed on the pixel defining layer, wherein the common electrode has a disconnected portion along the undercut portion.

12. The method of claim 11, wherein the removing of the portion of the preliminary-pixel defining layer includes:
aligning a mask having an exposure opening on the preliminary-pixel defining layer;
exposing the preliminary-pixel defining layer; and
developing an exposed portion of the preliminary-pixel defining layer using a developer.

13. The method of claim 12, wherein the developer is infiltrated into an interface between the peripheral part and the preliminary-pixel defining layer to form the undercut portion.

14. The method of claim 12, further comprising:
forming a through pattern in the preliminary-pixel defining layer which exposes a top surface of the peripheral part through the preliminary-pixel defining layer after forming the preliminary-pixel defining layer.

15. The method of claim 14, wherein the developer is infiltrated into an interface between the peripheral part and the preliminary-pixel defining layer through the through pattern to form the undercut portion.

16. The method of claim 14, further comprising:
curing the preliminary-pixel defining layer after developing the exposed portion of the preliminary-pixel defining layer using the developer.

17. The method of claim 11, wherein the pixel defining layer has a forward-tapered shape with respect to the plurality of pixel electrodes, and
wherein the undercut portion is recessed from the lateral side of the pixel defining layer in a direction from the central part toward the peripheral part.

18. The method of claim 11, wherein a height of the undercut portion is gradually decreased in the direction from the central part toward the peripheral part.

19. The method of claim 11, wherein a height of the undercut portion which is disposed adjacent to the central part is higher than a height of the light emitting material disposed on the central part.

20. The method of claim 11, wherein the plurality of pixel electrodes include:
a first pixel electrode and a second pixel electrode disposed adjacent to each other,
wherein the undercut portion includes:
a first undercut portion overlapping a peripheral part of the first pixel electrode when viewed in a plan view; and
a second undercut portion overlapping a peripheral part of the second pixel electrode when viewed in a plan view, and
wherein the first undercut portion and the second undercut portion are interposed between a central part of the first pixel electrode and a central part of the second pixel electrode.
